(19) United States
(12) Patent Application Publication
(10) Pub. No.: US 2019/0204727 A1
(43) Pub. Date: Jul. 4, 2019

(54) PHOTORESIST AND PREPARATION METHOD THEREOF

(71) Applicant: Shenzhen China Star Optoelectronics Technology Co., Ltd., Shenzhen (CN)

(72) Inventor: Lixuan CHEN, Shenzhen (CN)

(21) Appl. No.: 15/993,936

(22) Filed: May 31, 2018

Related U.S. Application Data
(63) Continuation of application No. PCT/CN2018/077084, filed on Feb. 24, 2018.

(30) Foreign Application Priority Data
Dec. 28, 2017 (CN) 201711467218.8

(51) Int. Cl. G03F 1/20; G03F 1/22

(52) U.S. Cl. CPC G03F 1/20; G03F 1/22

(57) ABSTRACT

The present disclosure provides a photoresist and a preparation method thereof. The photoresist includes at least one kind of resin, a photoinitiator, a solvent, and at least one kind of scattering particle, and the at least one kind of scattering particle being configured to scatter ultraviolet light irradiated into the photoresist. The present disclosure may increase an exposure energy that the photoresist obtains during an exposure process, and thereby may reduce an exposure time required for the photoresist.

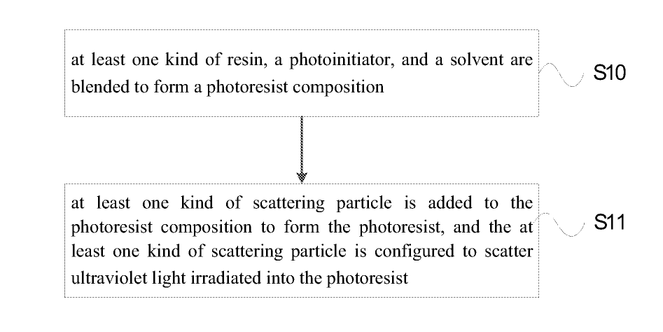

### CROSS-REFERENCE TO RELATED APPLICATIONS

The present application is a continuation-application of International (PCT) Patent Application No. PCT/CN2018/077084, field on Feb. 24, 2018, which claims foreign priority of Chinese Patent Application No. 201711467218.8, field on Dec. 28, 2017 in the State Intellectual Property Office of China, the entire contents of which are hereby incorporated by reference.

### FIELD

The present disclosure relates to a technology of a liquid crystal display manufacturing, and more particularly, to a photoresist and a preparation method thereof.

### BACKGROUND

A common photoresist consists of three major components: a photosensitive resin, a sensitizer (e.g., a spectral sensitizing dye) and a solvent. A mixed liquid by the above-mentioned components is light-sensitive. When the photosensitive resin is irradiated by light, a photocuring reaction can happen immediately in an exposure zone, so that obvious changes are occurred in physical properties of material, affinity, and other, especially in solubility.

In the fields of a liquid crystal display (LCD) and a semiconductor, a photolithography is a very common process. In an existing photoresist system, take a positive photoresist as an example, an exposure process is to wash away an area irradiated by ultraviolet light by developing solution, to remain a non-irradiated area for a purpose of patterning. In this process, defining a function: exposure dose (Dose)=exposure light energy (S)×exposure time (T). Because the exposure light energy of a light source during the exposure process is basically stable, an exposure time cannot be shortened when the Dose is required a certain value. In the modern technology, because a total time of a production process is directly affected by the exposure time, a production per unit of time is affected. To shorten the exposure time while maintaining a stable process is a necessary choice. Because of the material properties itself, especially the properties of a polymer itself, it is difficult to change the amount of Dose. In this case, it is necessary to consider how to increase the exposure energy that a photoresist material obtains actually.

In the related art, a solution is usually adopted. The solution is to add a bottom anti-reflective coating (BARC) between the photoresist and a substrate to be etched. However, the solution often causes a decrease of energy when light is reflected back to the photoresist system, so that the actual exposure energy is decreased.

### SUMMARY

The present disclosure provides a photoresist and a preparation method thereof, which may increase an exposure energy that the photoresist obtains during the exposure process, and thereby may reduce the exposure time required for the photoresist.

In order to solve the above-mentioned technical problem, a technical solution adopted by the present disclosure is to provide A method for preparing a photoresist comprising: blending at least one kind of resin, a photoinitiator, and a solvent to form a photoresist composition, the photoresist composition comprising molecular groups; adding at least one kind of scattering particle to the photoresist composition to form the photoresist, wherein the at least one kind of scattering particle is configured to scatter ultraviolet light irradiated into the photoresist and is at least one of an inorganic particle, a nanosphere and an organic polymer ball.

In order to solve the above-mentioned technical problem, a technical solution adopted by the present disclosure is to another provide a photoresist comprising at least one kind of resin, a photoinitiator, a solvent, and at least one kind of scattering particle, and the at least one kind of scattering particle being configured to scatter ultraviolet light irradiated into the photoresist.

The present disclosure has following beneficial effects: providing a photoresist and a preparation method thereof, by adding at least a scattering particle, an exposure energy that the photoresist obtains during an exposure process, may be increased, and thereby an exposure time required for the photoresist may be reduced.

### BRIEF DESCRIPTION OF THE DRAWINGS

FIGURE is a flow chart of a preparation method of a photoresist in accordance with an embodiment in the present disclosure.

### DESCRIPTION OF PREFERRED EMBODIMENT

The detailed description set forth below is intended as a description of the subject technology with reference to the appended FIGURES and embodiments. It is understood that the embodiments described herein include merely some parts of the embodiments of the present disclosure, but do not include all the embodiments. Based on the embodiments of the present disclosure, all other embodiments that those skilled in the art may derive from these embodiments are within the scope of the present disclosure.

A photoresist provided in the present embodiment may comprise following components: at least one kind of resin, a photoinitiator, a solvent, and at least one kind of scattering particle.

The at least one kind of resin in the present disclosure may be a photosensitive resin, and the photosensitive resin may refer to a material which is non-silver and light-sensitive. The material may generate patterns by using some polymers having characteristics of photolysis, or by using some monomers having characteristics of photopolymerization or photocrosslinking. In a specific embodiment, the photosensitive resin in the photoresist may be selected from the group consisting of an alkali-soluble resin, a thermosetting resin, and a combination of both.

The photoinitiator may be selected from the group consisting of a free-radical type photoinitiator, a cationic type photoinitiator, and a combination of a radical type photoinitiator and a cationic type photoinitiator. The photoinitiator may be configured to occur a free-radical polymerization and/or a cationic polymerization when corresponding components are irradiated with ultraviolet light. In a specific embodiment, the photoinitiator may be selected from the group consisting of a ketone oxime ester photoinitiator, an a-amino ketone photoinitiator, an acetophenone photoinitiator, an aromatic ketone photoinitiator, one kind of macroinitiator, and a combination of macroinitiators in any ratio.

The solvent may comprise one of acidic solvent, alkaline solvent, and neutral solvent. The acidic solvent may include, but not be limited to formic acid, acetic acid, and chloroform. The alkaline solvent may include, but not be limited to ketone, ester, ethers, and aromatic hydrocarbon. The neutral solvent may include, but not be limited to aliphatic hydrocarbon, naphthenic compound, and aromatic hydrocarbon. In a specific embodiment, the solvent may comprise at least one of fatty alcohol, glycol ether, ethyl acetate, methyl ethyl ketone, methyl isobutyl ketone, monomethyl ether ethylene glycol ester, butyl carbitol, butyl carbitol acetate, propylene glycol monomethyl ether, propylene glycol monomethyl ether acetate, cyclohexanone, xylene, isopropanol, and n-butanol. In other embodiments, it may be composed of other compounds, and which is not further limited herein.

The at least one kind of scattering particle may scatter ultraviolet light irradiated into the photoresist. The scattering may comprise a Rayleigh scattering and a Mie scattering. The photoresist in a patterned area may sufficiently absorb the ultraviolet light, to increase an exposure energy that the photoresist obtains during an exposure process. The at least one kind of scattering particle may be at least one of an inorganic particle, a nanosphere, and an organic polymer ball. In a specific embodiment, the at least one kind of scattering particle may specifically be silicon oxide, poly(alkyl cyanoacrylate) (PACA), poly(methyl methacrylate) (PMMA), and so on, and which is not further limited herein.

Further, in order to achieve a stronger scattering, the at least one kind of scattering particle may have a diameter of 100-2000 nm. Specifically, the diameter of the at least one kind of scattering particle may be 100 nm, 1050 nm, 2000 nm, and so on, which is not further limited herein. A feature of the at least one kind of scattering particle in the present disclosure, is that there may be no or only a little ultraviolet light absorbed by the at least one kind of scattering particle, i.e., the at least one kind of scattering particle adopted in the present disclosure may not react with components in an original photoresist system, and the at least one kind of scattering particle may not absorb the ultraviolet light. The at least one kind of scattering particle may only change a direction of the ultraviolet light propagation, so that light beams of the ultraviolet light may deviate from the original propagation direction and spread around. Furthermore, a surface refractive index of the at least one kind of scattering particle may be not less than 1.8. Specifically, the surface refractive index of the at least one kind of scattering particle may be 2.8, 3.8, 4.8, and so on, and which is not further limited herein.

Further, the at least one kind of scattering particles may be evenly distributed in the photoresist by following three manners.

1. The at least one kind of scattering particle may be connected to a molecular group in the photoresist by a physical blending manner, which refers to a blending of the above-mentioned organic and inorganic particle. The physical blending manner may be simple and easy to operate, and a concentration of components may be controlled easily. However, in a specific operation, in order to prevent an agglomeration of the inorganic particle, a surface treatment may be necessary before blending, such as an integrated treatment of a dispersant, a coupling agent, and/or a surface modifier, and so on. In addition, the blending may also be assisted by using ultrasonic, and which is not further limited herein.

2. The at least one kind of scattering particle may be connected to a molecular group in the photoresist by a side-chain connection manner. In a specific embodiment, a surface of the at least one kind of scattering particle (which may be the inorganic particle) may be processed hydroxylation, so that the at least one kind of scattering particle may be introduced an —OH bond, and may be connected to the molecular group in the original photoresist system by the side-chain connection manner.

3. The at least one kind of scattering particle may be distributed in the photoresist by a core-shell structure coating manner, i.e., in a specific embodiment, the at least one kind of scattering particle may be coated by using the photoresist as a core, so that the at least one kind of scattering particle may be evenly distributed in the photoresist system, and properties of the patterned photoresist under the ultraviolet light may not be affected by additional chemical reactions.

In other embodiments, other manners may be adopted for evenly distributing the at least one kind of scattering particle in the photoresist system, which is not further limited herein.

The photoresist provided in the present disclosure may further comprise a photopolymerizable monomer, an additive, a pigment, and so on. The pigment may be a blue pigment, a blue and violet mixed pigment, a green pigment, a green and yellow mixed pigment, a black pigment, and so on, which is not further limited herein. The additive may comprise a surfactant, a defoamer, a light stabilizer, an antioxidants, a solidification accelerator, and any combination of the above-mentioned materials.

In the above-mentioned embodiment, by adding the at least one kind of scattering particle, the exposure energy that the photoresist obtains during the exposure process, may be increased, and thereby the exposure time required for the photoresist may be reduced.

Referring to the FIGURE, the FIGURE is a flow chart of a preparation method of a photoresist in accordance with an embodiment in the present disclosure.

S10, at least one kind of resin, a photoinitiator, and a solvent are blended to form a photoresist composition.

In a specific embodiment, the preparation method of the photoresist composition may be referred to general preparations in the related art, therefore no additional description is given herebelow. In addition, the photoresist composition of the present embodiment may comprise at least one kind of resin, a photoinitiator, and a solvent.

The at least one kind of resin in the present disclosure may be a photosensitive resin, and the photosensitive resin may refer to a material which is non-silver and light-sensitive. The material may generate patterns by using some polymers having characteristics of photolysis, or by using some monomers having characteristics of photopolymerization or photocrosslinking. In a specific embodiment, the photosensitive resin in the photoresist may be selected from the group consisting of an alkali-soluble resin, a thermosetting resin, and a combination of both.

The photoinitiator may be selected from the group consisting of a free-radical type photoinitiator, a cationic type photoinitiator, and a combination of a radical type photoinitiator and a cationic type photoinitiator. The photoinitiator may be configured to occur a free-radical polymerization and/or a cationic polymerization when corresponding components are irradiated with ultraviolet light. In a specific embodiment, the photoinitiator may be selected from the group consisting of a ketone oxime ester photoinitiator, an a-amino ketone photoinitiator, an acetophenone photoinitiator, an aromatic ketone photoinitiator, one kind of macroinitiator, and a combination of macroinitiators in any ratio.

The solvent may comprise one of acidic solvent, alkaline solvent, and neutral solvent. The acidic solvent may include, but not be limited to formic acid, acetic acid, and chloroform. The alkaline solvent may include, but not be limited to ketone, ester, ethers, and aromatic hydrocarbon. The neutral solvent may include, but not be limited to aliphatic hydrocarbon, naphthenic compound, and aromatic hydrocarbon. In a specific embodiment, the solvent may comprise at least one of fatty alcohol, glycol ether, ethyl acetate, methyl ethyl ketone, methyl isobutyl ketone, monomethyl ether ethylene glycol ester, butyl carbitol, butyl carbitol acetate, propylene glycol monomethyl ether, propylene glycol monomethyl ether acetate, cyclohexanone, xylene, isopropanol, and n-butanol. In other embodiments, it may be composed of other compounds, and which is not further limited herein.

The photoresist provided in the present disclosure may further comprise a photopolymerizable monomer, an additive, a pigment, and so on. The pigment may be a blue pigment, a blue and violet mixed pigment, a green pigment, a green and yellow mixed pigment, a black pigment, and so on, which is not further limited herein. The additive may comprise a surfactant, a defoamer, a light stabilizer, an antioxidants, a solidification accelerator, and any combination of the above-mentioned materials.

S11, at least one kind of scattering particle is added to the photoresist composition to form the photoresist, and the at least one kind of scattering particle is configured to scatter ultraviolet light irradiated into the photoresist.

In the above-mentioned photoresist system, preparing at least one kind of scattering particle further. The at least one kind of scattering particle may scatter ultraviolet light irradiated into the photoresist. The scattering may comprise a Rayleigh scattering and a Mie scattering. The photoresist in the patterned area may sufficiently absorb the ultraviolet light, to increase an exposure energy that the photoresist obtains during an exposure process. The at least one kind of scattering particle may be at least one of an inorganic particle, a nanosphere and an organic polymer ball. In a specific embodiment, the at least one kind of scattering particle may specifically be silicon oxide, poly(alkyl cyanoacrylate) (PACA), poly(methyl methacrylate) (PMMA), and so on, and which is not further limited herein.

Further, in order to achieve a stronger scattering, the at least one kind of scattering particle may have a diameter of 100-2000 nm. Specifically, the diameter of the at least one kind of scattering particle may be 100 nm, 1050 nm, 2000 nm, and so on, which is not further limited herein. A feature of the at least one kind of scattering particle in the present disclosure, is that there may be no or only a little ultraviolet light absorbed by the at least one kind of scattering particle, i.e., the at least one kind of scattering particle adopted in the present disclosure may not react with components in an original photoresist system, and the at least one kind of scattering particle may not absorb the ultraviolet light. The at least one kind of scattering particle may only change a direction of the ultraviolet light propagation, so that light beams of the ultraviolet light may deviate from the original propagation direction and spread around. Furthermore, a surface refractive index of the at least one kind of scattering particle may be not less than 1.8. Specifically, the surface refractive index of the at least one kind of scattering particle may be 2.8, 3.8, 4.8, and so on, and which is not further limited herein.

Specifically, the adopted preparation method may be following three manners.

1. The at least one kind of scattering particle may be connected to a molecular group in the photoresist by a physical blending manner, which refers to a blending of the above-mentioned organic and inorganic particle. The physical blending manner may be simple and easy to operate, and a concentration of components may be controlled easily. However, in a specific operation, in order to prevent an agglomeration of the inorganic particle, a surface treatment may be necessary before blending, such as an integrated treatment of a dispersant, a coupling agent, and/or a surface modifier, and so on. In addition, the blending may also be assisted by using ultrasonic, and which is not further limited herein.

2. The at least one kind of scattering particle may be connected to a molecular group in the photoresist by a side-chain connection manner. In a specific embodiment, a surface of the at least one kind of scattering particle (which may be the inorganic particle) may be processed hydroxylation, so that the at least one kind of scattering particle may be introduced an —OH bond, and may be connected to the molecular group in the original photoresist system by the side-chain connection manner.

3. The at least one kind of scattering particle may be distributed in the photoresist by a core-shell structure coating manner, i.e., in a specific embodiment, the at least one kind of scattering particle may be coated by using the photoresist as a core, so that the at least one kind of scattering particle may be evenly distributed in the photoresist system, and properties of the patterned photoresist under the ultraviolet light may not be affected by additional chemical reactions.

In other embodiments, other manners may be adopted for evenly distributing the at least one kind of scattering particle in the photoresist system, which is not further limited herein.

In the above-mentioned embodiment, by adding the at least one kind of scattering particle, the exposure energy that the photoresist obtains during the exposure process, may be increased, and thereby the exposure time required for the photoresist may be reduced.

In summary, skilled in the art may easily understand that the present disclosure provides the photoresist and the preparation method thereof, by adding the at least one kind of scattering particle, the exposure energy that the photoresist obtains during the exposure process, may be increased, and thereby the exposure time required for the photoresist may be reduced.

It is understood that the descriptions above are only embodiments of the present disclosure. It is not intended to limit the scope of the present disclosure. Any equivalent transformation in structure and/or in scheme referring to the instruction and the accompanying drawings of the present disclosure, and direct or indirect application in other related technical field, are included within the scope of the present disclosure.

What is claimed is:

1. A method for preparing a photoresist comprising:
blending at least a resin, a photoinitiator, and a solvent to form a photoresist composition, the photoresist composition further comprising defining a molecular group;
adding at least one kind of ultraviolet light scattering particle to the photoresist composition to form the photoresist, wherein the at least one kind of scattering particle is configured to scatter ultraviolet light irradiated into the photoresist and is made of at least one of an inorganic particle, a nanosphere and an organic polymer ball;
wherein the at least one kind of scattering particles is distributed in the photoresist by selected in the group consisting of a physical blending manner, a side-chain connection manner, and a core-shell structure coating manner.

2. The method according to claim 1, wherein the at least one kind of scattering particle has a diameter of 100-2000 nm.

3. The method according to claim 1, wherein a surface refractive index of the at least one kind of scattering particle is not less than 1.8.

4. The method according to claim 1, wherein the at least one kind of scattering particle is distributed in the photoresist by the physical blending manner; the molecular group and the at least one kind of scattering particles are blended mechanically.

5. The method according to claim 1, wherein the at least one kind of scattering particle is distributed in the photoresist and connected to the molecular group by the side-chain connection manner; the at least one kind of scattering particle is introduced to an —OH bond to connect to the molecular group.

6. The method according to claim 1, wherein the at least one kind of scattering particle is distributed in the photoresist by the core-shell structure coating manner; the molecular group is configured as a core and the at least one kind of scattering particle as a coating layer, the at least one kind of scattering particle is coated on the molecular group.

7. A photoresist comprising at least a resin, a photoinitiator, a solvent, and at least one kind of scattering particle, and the at least one kind of scattering particle being configured to scatter ultraviolet light irradiated into the photoresist.

8. The photoresist according to claim 7, wherein the at least one kind of scattering particle is made of at least one of an inorganic particle, a nanosphere, and an organic polymer ball.

9. The photoresist according to claim 8, wherein the at least one kind of scattering particle has a diameter of 100-2000 nm, the photoresist further comprising a molecular group.

10. The photoresist according to claim 8, wherein a surface refractive index of the at least one kind of scattering particle is not less than 1.8.

11. The photoresist according to claim 8, wherein the at least one kind of scattering particle is distributed in the photoresist by a physical blending manner; the molecular group in the photoresist and the at least one kind of scattering particles are blended mechanically.

12. The photoresist according to claim 8, wherein the at least one kind of scattering particle is distributed in the photoresist and connected to the molecular group by a side-chain connection manner; the at least one kind of scattering particle is introduced to an —OH bond to connect to the molecular group.

13. The photoresist according to claim 8, wherein the at least one kind of scattering particle is distributed in the photoresist by a core-shell structure coating manner; the molecular group is configured as a core and the at least one kind of scattering particle as a coating layer, the at least one kind of scattering particle is coated on the molecular group.
